(19) United States
(12) Patent Application Publication
(10) Pub. No.: US 2025/0188223 A1
(43) Pub. Date: Jun. 12, 2025

(54) POLYIMIDES COMPRISING NOVEL INDANE BIS-O-AMINOPHENOLS, PHOTOSENSITIVE COMPOSITIONS, DIELECTRIC FILMS, AND BUFFER COATINGS CONTAINING THE SAME

(71) Applicant: Fujifilm Electronic Materials U.S.A., Inc., N. Kingstown, RI (US)

(72) Inventors: Binod B. De, Attleboro, MA (US); Sanjay Malik, Attleboro, MA (US)

(21) Appl. No.: 18/954,951

(22) Filed: Nov. 21, 2024

Related U.S. Application Data
(60) Provisional application No. 63/608,471, filed on Dec. 11, 2023.

(51) Int. Cl. C08G 73/10; G03F 7/038; G03F 7/039; G03F 7/16; H01L 23/29

(52) U.S. Cl. CPC C08G 73/1085; G03F 7/0387; G03F 7/0392; G03F 7/168; H01L 23/293

(57) ABSTRACT

Preparation of polyimides and functional polyimides comprising novel indane bis-o-aminophenols and photosensitive compositions obtained therefrom are described.

### CROSS-REFERENCE TO RELATED APPLICATION

The present application claims priority to U.S. Provisional Application Ser. No. 63/608,471, filed on Dec. 11, 2023, the contents of which are hereby incorporated by reference in their entirety.

### TECHNICAL FIELD

The disclosure relates to polyimides comprising indane bis-o-aminophenols as diamine monomers, and dielectric film-forming compositions prepared therefrom.

### BACKGROUND

Dielectric material requirements for semiconductor packaging applications are continuously evolving. The trend in electronic packaging continues to move towards faster processing speeds, increased complexity and higher packing density while maintaining a high level of reliability. As electronic packaging technology advances and chips continue to shrink in size, the demand for innovative and high-performance resin compositions is growing.

### SUMMARY

The disclosure provides polyimides comprising indane bis-o-aminophenols as diamine monomers, and dielectric film-forming compositions prepared therefrom. The dielectric film-forming compositions of the disclosure meet the exceedingly challenging requirements of the microelectronics industry. In some embodiments of the disclosure, there are provided dielectric film-forming compositions comprising (a) at least one polyimide comprising at least one indane bis-o-aminophenol of formula 1a as a diamine monomer:

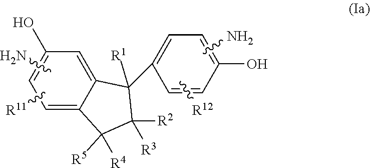

wherein each of R¹, R², R³, R⁴, and R⁵ independently, is a hydrogen atom, a substituted or unsubstituted C₁-C₁₂ alkyl, a partially halogen substituted or fully halogen substituted C₁-C₁₂ alkyl, a substituted or unsubstituted C₄-C₁₈ cycloalkyl, a substituted or unsubstituted C₆-C₂₂ aryl, or a substituted or unsubstituted C₅-C₂₂ heteroaryl; each of R¹¹ and R¹² is a hydrogen atom, a linear or branched C₁-C₄ alkyl, C₄-C₁₂ cycloalkyl, C₆-C₁₈ aryl, C₅-C₁₈ heteroaryl group, C₁-C₄ alkoxy group or a halogen atom.

Polyimides of the present disclosure can be used in different photosensitive compositions to provide a positive tone or a negative tone photosensitive composition, wherein both photosensitive compositions are soluble in an aqueous alkaline solution, can form a fine pattern, and can achieve high resolution.

In some embodiments of the disclosure, there are provided dielectric layers which can be cast from compositions of the disclosure. Dielectric layers of this disclosure can form uniform films which can be developed after exposure to relatively long UV wavelength (e.g., about 365 nm) to form a patterned dielectric film. When dielectric layers of the disclosure are present in a microelectronic device, the dielectric layer imparts good reliability to the device.

The dielectric layer can be cast from a dielectric film-forming composition of the disclosure. Compositions of the disclosure can form uniform films which can be developed after exposure to relatively long UV wavelength (e.g., about 365 nm) to form a patterned dielectric film, wherein the patterned dielectric film can exhibit desirable properties according to one or more reliability tests.

In some embodiments, the disclosure provides compositions that include a fully imidized polyimide comprising at least one indane bis-o-aminophenol compound and at least one solubility switching compound comprising a vinyl group, an allyl group, a vinyl ether group, a propenyl ether group, a (meth)acryloyl group, a SiH group, or a thiol group, wherein the dielectric composition is suitable to provide a dielectric layer that imparts good reliability to a microelectronic device when the dielectric layer is present in the device.

Other aspects, embodiments, and advantages follow.

### DETAILED DESCRIPTION

In general, this disclosure relates to polyimides, dielectric film-forming compositions, as well as related processes, dry films, and dielectric films. In some embodiments, the dielectric film-forming compositions described herein include (a) at least one polyimide comprising at least one indane bis-o-aminophenol as a diamine monomer. In some embodiments, the dielectric film-forming compositions described herein can be photosensitive and/or heat-curable.

The disclosure provides polyimides containing at least one indane bis-o-aminophenol monomer. Such monomers are suitable for the preparation of polymers that meet the highly challenging requirements of the microelectronics industry. The presence of indane bis-o-aminophenol monomers of the disclosure in polyimides obtained therefrom provide readily soluble fully cyclized polyimides with high temperature stability. The disclosure also provides fully cyclized polyimides containing functional groups, wherein the functional groups are selected from substituted or unsubstituted linear alkenyl groups, substituted or unsubstituted linear alkynyl groups, (meth)acrylic groups, or hydroxyl groups.

The disclosure provides indane bis-o-aminophenol compounds, comprising an indane moiety of Structure 1a;

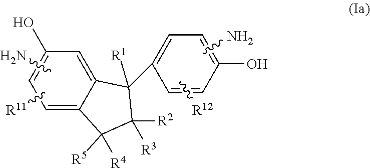

wherein each of R¹, R², R³, R⁴, and R⁵ independently, is a hydrogen atom, a substituted or unsubstituted C₁-C₁₂ alkyl, a partially halogen substituted or fully halogen substituted C₁-C₁₂ alkyl, a substituted or unsubstituted C₄-C₁₈ cycloalkyl, a substituted or unsubstituted C₆-C₂₂ aryl, or a substituted or unsubstituted C₅-C₂₂ heteroaryl; each of R¹¹ and R¹² is a hydrogen atom, a linear or branched C₁-C₄ alkyl, C₅-C₁₂ cycloalkyl, C₆-C₁₈ aryl, C₅-C₁₈ heteroaryl group, C₁-C₄ alkoxy group or a halogen atom.

In some embodiments, the dielectric film forming compositions set forth herein include at least one fully imidized polyimide. In some embodiments the fully imidized polyimide has structure (II):

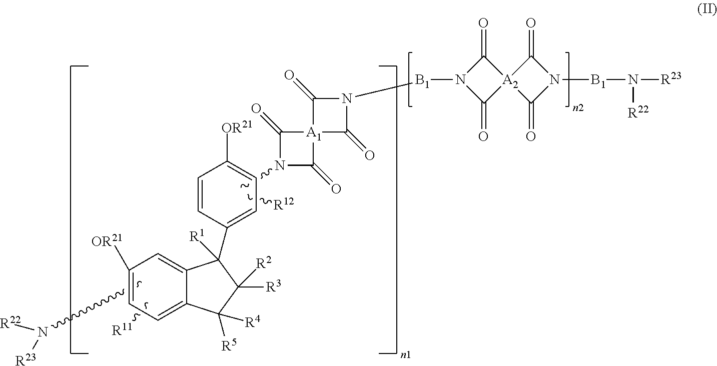

wherein R²¹ is a hydrogen or a C₁-C₁₂ alkenyl group, R²² is a hydrogen or a C₁-C₁₂ alkyl, C₂-C₁₂ alkenyl, C₄-C₁₈ cycloalkyl, C₆-C₂₂ aryl, or C₅-C₂₂ heteroaryl group; R²³ is an end group wherein at least one monoanhydride compound is added to the polymerization system for termination of chain growth of a polyamic acid, n1 is an integer greater than 1 (e.g., 1-200), n2 is an integer greater than or equal to 2 (e.g., 2-200). Examples of R²¹ include, but are not limited to, hydrogen, acetyl, trifluoroacetyl, propionyl, trimethylacetyl and the like. Examples of R²² include, but are not limited to hydrogen, methyl, ethyl, allyl, phenyl and the like. Examples of R²³ include, but are not limited to acetyl, trifluoroacetyl, propionyl, trimethylacetyl and the like. Examples of such end groups (e.g., a functional or non-functional end group) are disclosed in, e.g., U.S. Pat. No. 10,781,341 the entire contents of which are herein incorporated by reference.

In Structure II, B₁ is the nucleus of a precursor diamine and A₁ and A₂ are each independently the nucleus of a precursor dianhydride where A₁ and A₂ may be the same or different. As used herein, when referring to the precursor diamine, “nucleus” refers to the moiety between two amine functional groups. When referring to the precursor dianhydride, “nucleus” refers to the moiety between two anhydride functional groups.

Examples of such diamines and dianhydrides are disclosed in, e.g., U.S. Pat. No. 9,695,284, the entire contents of which are herein incorporated by reference. Functional or non-functional acid anhydrides or acid chlorides can be used for end-capping of unreacted amine functionality on the amino-terminated polyamic acid.

In some embodiments, the dielectric film forming compositions include at least one fully imidized polyimide of structure (III): wherein R²², R²³, n1 and n2 have the same meaning as defined above. R²⁴ is a reactive functional group such as substituted or unsubstituted linear alkenyl groups, substituted or unsubstituted linear alkynyl groups or (meth)acryloyl groups, wherein these functional groups additionally react with crosslinkers. Other groups have the same meaning as defined above.

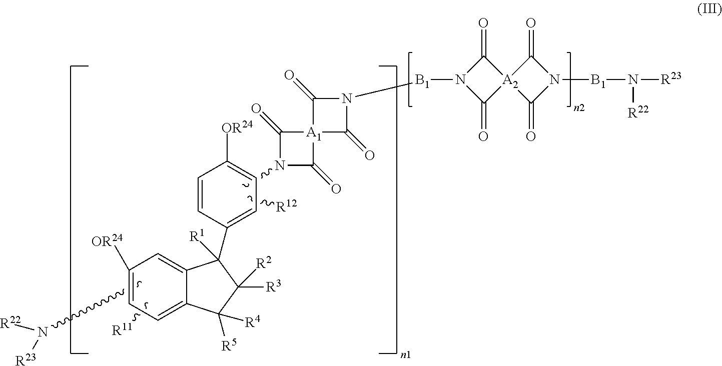

Examples of suitable diamines B₁ that can be used to prepare the polymer of structure (II or III) include, but are not limited to, 1-(4-aminophenyl)-1,3,3-trimethylindan-5-amine (alternative names including 4,4′-[1,4-phenylene-bis(1-methylethylidene)]bisaniline, 1-(4-aminophenyl)-1,3,3-trimethyl-2H-inden-5-amine, 1-(4-aminophenyl)-1,3,3-trimethyl-indan-5-amine, and [1-(4-aminophenyl)-1,3,3-trimethyl-indan-5-yl]amine), 1-(4-aminophenyl)-2,3-dihydro-1,3,3-trimethyl-1H-inden-5-amine, 5-amino-6-methyl-1-(3′-amino-4′-methylphenyl)-1,3,3-trimethylindan, 4-amino-6-methyl-1-(3′-amino-4′-methylphenyl)-1,3,3-trimethylindan, 5,7-diamino-1,1-dimethylindan, 4,7-diamino-1,1-dimethylindan, 5,7-diamino-1,1,4-trimethylindan, 5,7-diamino-1,1,6-trimethylindan, 5,7-diamino-1,1-dimethyl-4-ethylindan, p-phenylenediamine, m-phenylenediamine, o-phenylenediamine, 3-methyl-1,2-benzene-diamine, 1,2-diaminoethane, 1,3-diaminopropane, 1,4-diaminobutane, 1,5-diaminopentane, 1,6-diaminohexane, 1,7-diaminoheptane, 1,8-diaminooctane, 1,9-diaminononane, 1,10-diaminodecane, 1,2-diaminocyclohexane, 1,4-diaminocyclohexane, 1,3-cyclohexanebis(methylamine), 5-amino-1,3,3-trimethyl cyclohexanemethanamine, 2,5-diaminobenzotrifluoride, 3,5-diaminobenzotrifluoride, 1,3-diamino-2,4,5,6-tetrafluorobenzene, 4,4′-oxydianiline, 3,4′-oxydianiline, 3,3′-oxydianiline, 3,3′-diaminodiphenylsulfone, 4,4′-diaminodiphenylsulfone, 4,4′-isopropylidenedianiline, 4,4′-diaminodiphenylmethane, 2,2-bis(4-aminophenyl) propane, 4,4′ diaminodiphenyl propane, 4,4′-diaminodiphenyl sulfide, 4,4′-diaminodiphenylsulfone, 4-aminophenyl-3-aminobenzoate, 2,2′-dimethyl-4,4′-diaminobiphenyl, 3,3′-dimethyl-4,4′-diaminobiphenyl, 2,2′-bis(trifluoromethyl)benzidine, 3,3′-bis(trifluoromethyl)benzidine, 2,2-bis[4-(4-aminophenoxyphenyl)]hexafluoropropane, 2,2-bis(3-amino-4-methylphenyl)-hexafluoropropane, 2,2-bis(3-aminophenyl)-1,1,1,3,3,3-hexafluoropropane, 1,3-bis-(4-aminophenoxy)benzene, 1,3-bis-(3-aminophenoxy)benzene, 1,4-bis-(4-aminophenoxy)benzene, 1,4-bis-(3-aminophenoxy)benzene, 1-(4-aminophenoxy)-3-(3-aminophenoxy)benzene, 2,2′-bis-(4-phenoxyaniline) isopropylidene, bis(p-beta-amino-t-butylphenyl) ether, p-bis-2-(2-methyl-4-aminopentyl)benzene, p-bis(1,1-dimethyl-5-aminopentyl)benzene, 3,3′-dimethyl-4,4′-diaminobiphenyl, 4,4′-diaminobenzophenone, 3′-dichlorobenzidine, 2,2-bis[4-(4-aminophenoxy)phenyl]propane, 4,4′-[1,3-phenylenebis(1-methyl-ethylidene)]bisaniline, 4,4′-[1,4-phenylenebis(1-methyl-ethylidene)]bisaniline, 2,2-bis[4-(4-aminophenoxy)phenyl]sulfone, 2,2-bis[4-(3-aminophenoxy)benzene], 1,4-bis(4-aminophenoxy)benzene, 1,3-bis(4-aminophenoxy)benzene, 1,3′-bis(3-aminophenoxy)benzene,4,4′-diamino-2,2′-bis(trifluoromethyl) biphenyl, H-fluorene-2,6-diamine, bis(aminopropyl)tetramethyldisiloxane (BATMS), bis(aminopropyl)tetraphenyldisiloxane, bis(4-aminophenoxy)dimethylsilane and the like.

Examples of such diamines are disclosed in, e.g., U.S. Pat. Nos. 10,604,628; 10,781,341; 10,793, 676 and the entire contents of which are herein incorporated by reference. Any of these diamines can be used individually or in combination in any suitable ratio to form a polyimide described herein.

Examples of suitable dianhydrides that can be used to prepare the polymer of structure (II or III) include, but are not limited to, 1-(3′,4′-dicarboxyphenyl)-1,3,3-trimethylindan-5,6-dicarboxylic acid dianhydride, 1-(3′,4′-dicarboxyphenyl)-1,3,3-trimethylindan-6,7-dicarboxylic acid dianhydride, 1-(3′,4′-dicarboxyphenyl)-3-methylindan-5,6-dicarboxylic acid dianhydride, 1-(3′,4′-dicarboxyphenyl)-3-methylindan-6,7-dicarboxylic acid anhydride, pyromellitic dianhydride, benzene-1,2,3,4-tetracarboxylic dianhydride, 2,3,5,6-naphthalenetetracarboxylic acid dianhydride, 2,3,6,7-naphthalenetetracarboxylic acid dianhydride, 1,4,5,8-naphthalenetetracarboxylic acid dianhydride, 2,6-dichloronaphthalene-1,4,5,8-tetracarboxylic dianhydride, 2,7-dichloronaphthalene-1,4,5,8-tetracarboxylic dianhydride, 2,3,6,7-tetrachloronaphthalene-1,4,5,8-tetracarboxylic dianhydride, phenanthrene-,8,9,10-tetracarboxylic dianhydride, 3,4,9,10-perylenetetracarboxylic acid dianhydride, pyrazine-2,3,5,6-tetracarboxylic dianhydride, thiophene-2,3,4,5-tetracarboxylic dianhydride, 2,3,5,6-pyridinetetracarboxylic acid dianhydride, butane-1,2,3,4-tetracarboxylic acid dianhydride, 1,2,3,4-cyclopentanetetracarboxylic acid dianhydride, cyclobutane-1,2,3,4-tetracarboxylic acid dianhydride, cyclopentane-1,2,3,4-tetracarboxylic acid dianhydride, cyclohexane-1,2,4,5-tetracarboxylic acid dianhydride, norbornane-2,3,5,6-tetracarboxylic acid dianhydride, bicyclo[2.2.2]oct-7-ene-3,4,8,9-tetracarboxylic acid dianhydride, tetracyclo[4.4.1.0 2,5 0 7,10]undecane-1,2,3,4-tetracarboxylic acid dianhydride, 3,3′,4,4′-benzophenone tetracarboxylic dianhydride, 2,2′,3,3′-benzophenone tetracarboxylic dianhydride, 2,3,3′,4′-benzophenone tetracarboxylic dianhydride, 3,3′,4,4′-diphenylsulfone tetracarboxylic dianhydride, 2,2′,3,3′-diphenylsulfone tetracarboxylic dianhydride, 2,3,3′,4′-diphenylsulfone tetracarboxylic dianhydride, 3,3′,4,4′-diphenylether tetracarboxylic dianhydride, 2,2′,3,3′-diphenylether tetracarboxylic dianhydride, 2,3,3′,4′-diphenylether tetracarboxylic dianhydride, 2,2-[bis(3,4-dicarboxyphenyl)]hexafluoropropane dianhydride, ethyleneglycol bis(anhydrotrimellitate), and 5-(2,5-dioxotetrahydro)-3-methyl-3-cyclohexene-1,2-dicarboxylic anhydride. Examples of such dianhydrides are disclosed in, e.g., U.S. U.S. Pat. Nos. 10,604,628; 10,781,341; 10,793, 676 and the entire contents of which are herein incorporated by reference. Any of these tetracarboxylic acid dianhydrides can be used individually or in combination in any suitable ratio to form a polyimide described herein.

In some embodiments, the second step of the polyamic acid synthesis can be carried out by reacting an amino-terminated polyamic acid with a monoanhydride to yield an end-capped polyamic acid. In some embodiments, the end-capped polyamic acid can be used for further reaction without isolation. In other embodiments, when a cyclic monoanhydride is used for termination of an amino group, an amic acid is formed. The amic acid is subsequently cyclized to an imide end group during imidization of polyamic acid to fully cyclized polyimide. Monoanhydrides contemplated for use in this aspect of the disclosure include, for example, aliphatic acid anhydride, such as acetic anhydride, trifluoroacetic anhydride, pivalic anhydride, or cyclic anhydrides such as 1,1-cyclopentanediacetic anhydride, succinic anhydride, or maleic anhydride. Further examples of end-capping groups are disclosed in, e.g., U.S. Pat. No. 9,695,284, the entire contents of which are herein incorporated by reference.

In some embodiments, the fully imidized polyimide described herein is at least about 90% (e.g., at least about 95%, at least about 98%, at least about 99%, or about 100%) imidized. Evidence of level of imidization and formation of a polyimide structure is confirmed by observation of characteristic absorptions in the infrared spectrum from 1770 and 1700 cm-1 attributable to the imide ring structure.

In some embodiments, the weight average molecular weight of the fully imidized polyimide is at least about 20,000 Daltons (e.g., at least about 25,000 Daltons, at least about 30,000 Daltons, at least about 35,000 Daltons, at least about 40,000 Daltons, at least about 45,000 Daltons, at least about 50,000 Daltons, or at least about 55,000 Daltons) and/or at most about 100,000 Daltons (e.g., at most about 95,000 Daltons, at most about 90,000 Daltons, at most about 85,000 Daltons, at most about 80,000 Daltons, at most about 75,000 Daltons, at most about 70,000 Daltons, at most about 65,000 Daltons, or at most about 60,000 Daltons).

In some embodiments, the molar ratio of diamine component(s) to tetracarboxylic acid dianhydrides component(s) is from between 1.01 to 1.20. In some embodiments a molar ratio of diamine to diacid chloride of about 1.02 to 1.10 is employed. Note that when the molar ratio of diamine component(s) to tetracarboxylic acid dianhydrides component(s) is greater than 1.00, the resulting species is an amino-terminated polyamic acid, which can be further reacted with an end-capping monomer to form an end-capped polymer.

The disclosure provides polyimides comprising indane bis-o-aminophenols as diamine monomers in the diamine components of fully cyclized polyimides, where indane bis-o-aminophenols as diamine monomers represented by formula (Ia) are 1.0-90 mol % of the total amount of diamine components incorporated in a polyimide chain.

In some embodiments the indane bis-o-aminophenols as diamine monomers represented by formula (Ia) are 5-50 mol % in an amount of total diamine components incorporated in polyimide chain.

In some embodiments, the fully imidized polyimide is prepared by reaction of at least one diamine with at least one tetracarboxylic acid dianhydride. In some embodiments, the resulting polymer is soluble in the organic solvent of this disclosure to facilitate the formation of a dielectric film, such as a dielectric film with a planarized surface (e.g., the difference in the highest and lowest points on a top surface of the dielectric film is less than about 2 microns). Examples of the preparation method of fully imidized polyimides are known in the art and have been described, e.g., in U.S.

Application Publication No. 2019/0077913, the entire contents of which are hereby incorporated by reference.

Methods to synthesize end-capped and non-end-capped polyimide (PI) precursor polymers are well known to those skilled in the art. Examples of such methods and PI precursor polymers are disclosed in, e.g., US Patent Nos. U.S. Pat. Nos. 2,731,447, 3,435,002, 3,856,752, 3,983,092, 4,026,876, 4,040,831, 4,579,809, 4,629,777, 4,656,116, 4,960,860, 4,985,529, 5,006,611, 5,122,436, 5,252,534, US5,4789,15, U.S. Pat. Nos. 5,773,559, 5,783,656, 5,969,055, 9,617,386, and US Application Publication No. US2004/0265731, US2004/0235992, and US2007/0083016, the entire contents of which are hereby incorporated by reference.

In some embodiments, herein are disclosed processes for providing (a) an organic solution containing a fully imidized polyimide polymer in at least one polar, aprotic polymerization solvent; (b) adding at least one purification solvent to the organic solution to form a diluted organic solution, the at least one purification solvent is less polar than the at least one polymerization solvent and has a lower water solubility than the at least one polymerization solvent at 25° C.; (c) washing the diluted organic solution with acidified aqueous solution to obtain a washed organic solution; (d) repeating washing the dilute organic solution with water to obtain a washed polymerization solvent free organic soliton; (e) removing at least a portion of the at least one purification solvent in the washed organic solution to obtain a solution containing a purified fully imidized polyimide polymer wherein the process avoids precipitation of the fully imidized polyimide polymer.

In some embodiments, the fully imidized polyimide described herein can be an alkali soluble polyimide which has at least one (e.g., two or three) functional group such as a carboxylic acid group, a hydroxyl group (e.g., a phenolic hydroxyl group), a sulfonic acid group, or a thiol group (e.g., at one or both ends of a main chain, or at a side chain of the polymer). The term “alkali soluble” used herein means that the solubility in a 2.38 weight percent aqueous tetramethylammonium hydroxide solution at 25° C. is not less than about 0.1 g/100 mL.

In some embodiments, the amount of the indane bis-o-aminophenol containing polyimide present in the dielectric film-forming compositions of the disclosure is at least about 0.1 wt. % (e.g., at least about 0.5 wt. %, at least about 1 wt. %, at least about 2 wt. %, at least about 5 wt. %, at least about 10 wt. %, at least about 15 wt. %, or at least about 20 wt. %) and/or at most or about 55 wt. % (e.g., at most about 50 wt. %, at most about 45 wt. %, at most about 40 wt. %, at most about 35 wt. %, at most about 30 wt. %, at most about 25 wt. %, at most about 20 wt. %, at most about 15 wt. %, or at most about 10 wt. %) of the solid weight of the dielectric film forming compositions described herein.

In some embodiments, the dielectric film forming compositions described herein include at least one solubility switching compound (SSC) having at least one functional group capable of reacting with other functional groups present on the polyimide. Such functional groups present on the polyimide include, for example, substituted or unsubstituted linear alkenyl groups, substituted or unsubstituted linear alkynyl groups, (meth)acrylic groups, or hydroxyl groups. In some embodiments, the SSC can react with itself when there is no reactive functional group on the polyimide polymers. In this circumstance, the composition typically includes an initiator to facilitate self-crosslinking of the solubility switching compound.

The solubility switching compound (SSC) generally helps to generate a contrast in the dissolution rate between unexposed areas and exposed areas after exposure to actinic radiation. In some embodiments, the SSC can be a crosslinking agent, which can crosslink the polymers in the exposed area after exposure to actinic radiation, thereby reducing the solubilities of the exposed areas in a developer.

The solubility switching compound generally possesses at least one functional group or pendant reactive functional group capable of reacting with a terminal functional group on the polyimide polymer. The SSC can be a monomer or an oligomer. The oligomer can contain many monomer units and is capable of further reactions to be incorporated into the final composition. Examples of such monomer units/oligomers include acrylate, ester, vinyl alcohol, urethane, urea, imide, amide, carboxazole, carbonate, pyranose, siloxane, urea-formaldehyde and melamine-formaldehyde. The SSC generally contains at least one terminal and/or pendant reactive functional group capable of radical, thermal, or acid catalyzed reaction with the at least one functional group on the polyimide polymer.

Further examples of a solubility switching compound include, but are not limited to, compounds bearing a vinyl group, an allyl group, a vinyl ether group, a propenyl ether group, a hydrophobic multifunctional(meth)acrylate, an epoxy, a —SiH group and a —SH(thiol) group.

In some embodiments, the dielectric film forming compositions described herein include at least one (e.g., two, three, or four) hydrophobic multifunctional(meth)acrylate as a solubility switching compound. In some embodiments, the hydrophobic multifunctional(meth)acrylate compound can include an ethylenically unsaturated polymerizable compound (e.g., an ethylenically unsaturated photopolymerizable compound), a metal-containing (meth)acrylate compound, or mixtures thereof.

In some embodiments, the hydrophobic multifunctional(meth)acrylate compound described herein can include an ethylenically unsaturated polymerizable compound containing at least two(meth)acrylate groups. In some embodiments, the multifunctional(meth)acrylate compound is selected from the group consisting of 1,6-hexanediol di(meth)acrylate, tetraethyleneglycol di(meth)acrylate, 1,12-dodecanediol di(meth)acrylate, 1,3-butylene glycol di(meth)acrylate, 1,4-butanediol di(meth)acrylate, cyclohexane dimethanol di(meth)acrylate, polyethylene glycol di(meth)acrylate, propoxylated (3)glycerol tri(meth)acrylate or tri-propoxylated glycerol triacrylate, ethoxylated bisphenol-A-di(meth)acrylate, trimethylolpropane tri(meth)acrylate, ditrimethylolpropane tetra(meth)acrylate, pentaerythritol tri(meth)acrylate, pentaerythritol tetra(meth)acrylate, dipentaerythritol penta-/hexa-(meth)acrylate, isocyanurate tri(meth)acrylate, bis(2-hydroxyethyl)-isocyanurate di(meth)acrylate, 1,3-butanediol tri(meth)acrylate, 1,4-butanediol tri(meth)acrylate, neopentyl glycol di(meth)acrylate, (meth)acrylate modified-urea-formaldehyde resins, (meth)acrylate modified melamine-formaldehyde resins, and (meth)acrylate modified cellulose. Other examples of such compounds are disclosed in, e.g., U.S. Pat. Nos. 10,036,952, 10,563,014, and U.S. Application Publication No. 2015/0219990, EP U.S. Pat. No. 3,492,982; the entire contents of which are hereby incorporated by reference.

In some embodiments, the crosslinker can be a metal-containing (meth)acrylate (MCA) compound. As used herein, the term “(meth)acrylate” refers to both acrylate compounds and methacrylate compounds. Examples of suitable MCAs include, but are not limited to, titanium tetra(meth)acrylate, zirconium tetra(meth)acrylate, hafnium tetra(meth)acrylate, titanium butoxide tri(meth)acrylate, titanium(meth)acryloxyethylacetoacetate triisopropoxide, titanium tris(2-ethylhexanoate) (carboxyethyl(meth)acrylate), titanium tetra(carboxyethyl(meth)acrylate), zirconium tetra(carboxyethyl(meth)acrylate), hafnium tetra(carboxyethyl(meth)acrylate), titanium butoxide tri (carboxyethyl(meth)acrylate), titanium dibutoxide di(carboxyethyl(meth)acrylate), titanium tributoxide (carboxyethyl(meth)acrylate), titanium oxide di(carboxyethyl(meth)acrylate), zirconium butoxide tri (carboxyethyl(meth)acrylate), zirconium dibutoxide di(carboxyethyl(meth)acrylate), zirconium tributoxide (carboxyethyl(meth)acrylate), zirconium oxide di(carboxyethyl(meth)acrylate), zirconium bis(2-ethylhexanoate)di(carboxyethyl(meth)acrylate Other examples of such compounds are disclosed in, e.g., U.S. Application Publication No. 2021/104398; the entire contents of which are hereby incorporated by reference.

In some embodiments, the crosslinker described herein can be in an amount of from at least about 0.5 wt. % (e.g., at least about 1 wt. %, at least about 2 wt. %, at least about 3 wt. %, at least about 4 wt. %, at least about 5 wt. %, at least about 6 wt. %, at least about 7 wt. %, at least about 8 wt. %, at least about 9 wt. %, at least about 10 wt. %) to at most about 35 w.t % (e.g., at most about 30 wt. %, at most about 28 wt. %, at most about 26 wt. %, at most about 24 wt. %, at most about 22 wt. %, at most about 20 wt. %, at most about 18 wt. %, at most about 16 wt. %, at most about 15 wt. %, at most about 14 wt. %, at most about 12 wt. %, at most about 10 wt. %, at most about 8 wt. %, at most about 6 wt. %, or at most about 5 wt. %) of the solid weight of a dielectric film forming composition described herein.

The dielectric film forming compositions described herein can optionally contain at least one (e.g., two, three, or four) radical initiator. As used herein, a radical initiator refers to a compound capable of generating free radicals that can initiate radical polymerization or crosslinking upon heating or irradiation with light at a certain wavelength range (e.g., from about 150 nm (e.g., about 157 nm) or about 600 nm). In some embodiments, the wavelength range is selected such that the radical initiator has absorption and the radically polymerizable monomer does not have substantial absorption. A photo-radical initiator (also referred to herein as a photoinitiator) and a thermal-radical initiator (also referred to herein as a thermal initiator) are examples of a radical initiator. In some embodiments, a photo-radical initiator is preferable.

In some embodiments, the amount of the radical initiator (e.g., a photoinitiator) is from at least about 0.1 wt. % (e.g., at least about 0.2 wt. %, at least about 0.5 wt. %, at least about 0.8 wt. %, at least about 1 wt. %, at least about 1.5 wt. %, at least about 2 wt. %, at least about 3 wt. %, at least about 4 wt. %, or at least about 5 wt. %) to at most about 10 wt. % (e.g., at most about 9 wt. %, at most about 8 wt. %, at most about 7 wt. %, at most about 6 wt. %, at most about 5 wt. %, at most about 4 wt. %, at most about 3 wt. %, at most about 2 wt. %, or at most about 1 wt. %) of the solid weight of a dielectric film forming composition described herein.

In some embodiments, a photoinitiator has photosensitivity to rays ranging from an ultraviolet ray region to a visible region. In some embodiments, the photoinitiator can be an activator which produces a free radical by some action with a photo-excited sensitizer. In some embodiments, the photoinitors are selected from group consisting of oxime ester, titanocene, acyl germanium compound, peroxide, and their mixture thereof.

One example of a photoinitiator is an oxime ester of structure (IV),

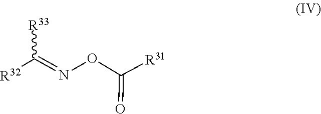

wherein each of R³¹ and R³², independently, is a substituted or unsubstituted C₁-C₁₂ alkyl, a substituted or unsubstituted C₄-C₁₈ cycloalkyl, a substituted or unsubstituted C₆-C₂₂ aryl, or a substituted or unsubstituted C₆-C₂₂ heteroaryl; and R³³ is a UV absorbing functional group (e.g., a substituted or unsubstituted C₆-C₂₂ aryl or a substituted or unsubstituted C₆-C₂₂ heteroaryl). In some embodiments, the alkyl, cycloalkyl, aryl, or heteroaryl described above is optionally substituted by at least one (e.g., two or three) C₁-C₄ alkyl, halogen, C₁-C₄ haloalkyl, —OR′, —OC(O)R′, or —COOR′, where R′ is H, C₁-C₄ alkyl, C₅-C₁₂ cycloalkyl, C₆-C₁₈ aryl, or C₆-C₁₈ heteroaryl.

Another example of a photoinitiator is an organic titanocene compound of structure (V):

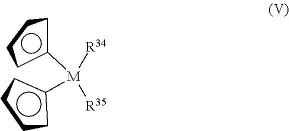

wherein M is selected from the group consisting of a titanium atom, a zirconium atom, and a hafnium atom; and each of R³⁴ and R³⁵, independently, is selected from the group consisting of substituted or unsubstituted C₁-C₁₂ alkyl, substituted or unsubstituted C₄-C₁₈ cycloalkyl, substituted or unsubstituted C₆-C₂₂ aryl, substituted or unsubstituted C₆-C₂₂ heteroaryl, a substituted or unsubstituted C₆-C₂₂ heteroaryl, or a substituted or unsubstituted alkylsulfonyloxy group (e.g., a substituted or unsubstituted C₁-C₁₂ alkylsulfonyloxy group). In some embodiments, the alkyl, cycloalkyl, aryl, or heteroaryl described above is optionally substituted by at least one (e.g., two or three) C₁-C₄ alkyl, halogen, C₁-C₄ haloalkyl, —OR′, —OC(O) R′, or —COOR′, where R′ is H, C₁-C₄ alkyl, C₅-C₁₂ cycloalkyl, C₆-C₁₈ aryl, or C₆-C₁₈ heteroaryl.

Commercial examples of photoinitiators include, but are not limited to, IRGACURE-784, IRGACURE OXE 01, IRGACURE OXE 02, IRGACURE OXE 03, IRGACURE OXE 04, and IRGACURE OXE 05 available from BASF; ADEKA OPTOMER N-1919, ADEKA ARKLS NCI-831, and ADEKA ARKLS NCI-930 available from ADEKA Corporation. Examples of other photoinitiators are disclosed in, e.g., EP U.S. Pat. No. 3,492,982, the entire contents of which are hereby incorporated by reference.

Examples of thermal initiators include, but are not limited to, benzoyl peroxide, cyclohexanone peroxide, lauroyl peroxide, tert-amyl peroxybenzoate, tert-butyl hydroperoxide, di(tert-butyl) peroxide, dicumyl peroxide, cumene hydroperoxide, succinic acid peroxide, di(n-propyl) peroxydicarbonate, 2,2-azobis(isobutyronitrile), 2,2-azobis(2,4-dimethylvaleronitrile), dimethyl-2,2-azobisisobutyrate, 4,4-azobis(4-cyanopentanoic acid), azobiscyclohexanecarbonitrile, 2,2-azobis(2-methylbutyronitrile) and the like.

In some embodiments, acyl germanium compound may use as photoinitiator. Suitable examples of the compounds of acyl germanium compound, but not limited to, (2,4,6-trimethylbenzoyl)triethylgermanium, (2,4,6-trimethylbenzoyl)tripropylgermanium, (2,4,6-trimethylbenzoyl)tributylgermanium, (2,6-dimethoxybenzoyl)triethylgermanium, (2.6-dimethoxybenzoyl)tripropylgermanium, (2,6-dimethoxybenzoyl)tributylgermanium, bisbenzoyldiethylgermanium, bisbenzoyldipropylgermanium, bis(4-methoxybenzoyl) diethylgermanium, bis(2,4,6-trimethylbenzoyl) diethylgermanium, trisbenzoylethylgermanium, tris(2,4,6-trimethylbenzoyl)ethylgermanium and the like. A commercial example of an acyl germanium compound is Ivocerin (i.e., bis(4-methoxybenzoyl) diethylgermanium). Other examples of such acyl germenium compounds are disclosed in, e.g., U.S. Pat. Nos. 7,605,190 and 9,532,930, the entire contents of which are hereby incorporated by reference.

In some embodiments, the dielectric film forming compositions described herein can include at least one (e.g., two, three, or four) photosensitizer different from the acyl germanium compound, where the photosensitizer can absorb light in the wavelength range of from about 150 nm to about 600 nm (e.g., at about 405 nm). Examples of suitable photosensitizers that can be used in the dielectric film forming composition include benzophenone compounds, thioxanthone compounds, anthraquinone compounds, anthracene compounds, coumarine compounds, and mixtures thereof. Specific examples of photosensitizers include, but are not limited to, 9-methylanthracene, 9,10-dibutoxyanthracene, 9,10-diethoxyanthracene, anthracenemethanol, acenaphthylene, thioxanthone, methyl-2-naphthyl ketone, 4-acetylbiphenyl, and 1,2-benzofluorene. Examples of other photosensitizers are disclosed in, e.g., U.S. Application Publication No. 2022/0171285, the entire contents of which are hereby incorporated by reference. In some embodiments, the acyl germanium compounds described herein can serve as a photosensitizer.

In some embodiments, the amount of a photosensitizer is from at least about 0.01 wt. % (e.g., at least about 0.05 wt. %, at least about 0.1 wt. %, or at least about 0.5 wt. %) to at most about 1 wt. % (e.g., at most about 0.8 wt. %, at most about 0.6 wt. %, at most about 0.5 wt. %, at most about 0.4 wt. %, at most about 0.2 wt. %, or at most about 0.1 wt. %) of the solid weight of a dielectric film forming composition described herein. In some embodiments, the dielectric film forming compositions described herein can further include an organic solvent or a mixture (e.g., two, three, or four) of organic solvents. In another embodiments, the solvents are selected from group consisting of alkylene carbonates, lactones, cycloketones, linear ketones, alkyl esters; alkyl ester alcohol, alkyl ether alcohols, alkyl ether ester, glycol ester; glycol ether, cyclic ether, pyrrolidone, and dialkylsulfoxide and their mixture thereof. Examples of organic solvents suitable for the dielectric film forming compositions described herein include, but are not limited to, alkylene carbonates such as ethylene carbonate, propylene carbonate, butylene carbonate, and glycerine carbonate; lactones such as gamma-butyrolactone,-caprolactone, y-caprolactone and γ-valerolactone; cycloketones such as cyclopentanone and cyclohexanone; linear ketones such as methyl ethyl ketone (MEK) and methyl isobutyl ketone (MIBK); esters such as n-butyl acetate; ester alcohol such as ethyl lactate; ether alcohols such as tetrahydrofurfuryl alcohol; ether ester such as (tetrahydrofuran-2-yl)methyl acetate, methyl-3-methoxypropionate, ethyl-3-ethoxypropionate and 3-methoxy butyl acetate; glycol esters such as propylene glycol methyl ether acetate; glycol ethers such as propylene glycol methyl ether (PGME); cyclic ethers such as tetrahydrofuran (THF); pyrrolidones such as N-methyl-2-pyrrolidone, N-ethyl-2-pyrrolidone or N-butyl-2-pyrrolidone or TamiSolve™ NxG; and dialkyl sulfoxide such as dimethyl sulfoxide.

In some embodiments, the total amount of the solvent is at least about 20 wt. % (e.g., at least about 25 wt. %, at least about 30 wt. %, at least about 35 wt. %, at least about 40 wt. %, at least about 45 wt. %, at least about 50 wt. %, at least about 55 wt. %, at least about 60 wt. %, or at least about 65 wt. %) and/or at most about 98 wt. % (e.g., at most about 95 wt. %, at most about 90 wt. %, at most about 85 wt. %, at most about 80 wt. %, at most about 75 wt. %, at most about 70 wt. %, or at most about 60 wt. %) of the total weight of the dielectric film forming compositions described herein.

In some embodiments, the dielectric film forming compositions described herein optionally includes at least one (e.g., two, three, or four) filler (such as an inorganic filler or an inorganic particle). In some embodiments, the inorganic filler is selected from the group consisting of silica, alumina, titania, zirconia, hafnium oxide, CdSe, CdS, CdTe, CuO, zinc oxide, lanthanum oxide, niobium oxide, tungsten oxide, strontium oxide, calcium titanium oxide, sodium titanate, barium sulfate, barium titanate, barium zirconate, and potassium niobate. Preferably, the inorganic fillers are in a granular form of an average size of about 0.1-2.0 microns. In some embodiments, the filler is an inorganic particle containing a ferromagnetic material. Suitable ferromagnetic materials include elemental metals (such as iron, nickel, and cobalt) or their oxides, sulfides and oxyhydroxides, and intermetallics compounds such as Awaruite (NisFe), Wairaruite (CoFe), Co₁₇Sm₂, and Nd₂Fe₁₄B.

In some embodiments, the amount of the inorganic filler (e.g., silica filler) is at least about 1 wt. % (e.g., at least about 2 wt. %, at least about 5 wt. %, at least about 8 wt. %, or at least about 10 wt. %) and/or at most about 30 wt % (e.g., at most about 25 wt. %, at most about 20 wt. %, or at most about 15 wt. %) of the solid weight of the dielectric film forming compositions described herein.

In some embodiments, the dielectric film forming compositions described herein can optionally further include at least one (e.g., two, three, or four) adhesion promoter. Suitable adhesion promoters are described in “Silane Coupling Agent” Edwin P. Plueddemann, 1982 Plenum Press, New York. Examples of such adhesion promoters are disclosed in, e.g., U.S. Pat. Nos. 10,036,952, 10,563,014, and U.S. Application Publication No. 2015/0219990, and EP Patent No. 3,492, 982; the entire contents of which are hereby incorporated by reference.

In some embodiments, the amount of the optional adhesion promoter is at least about 0.5 wt. % (e.g., at least about 0.8 wt. %, at least about 1 wt. %, or at least about 1.5 wt. %) and/or at most about 4 wt. % (e.g., at most about 3.5 wt. %, at most about 3 wt. %, at most about 2.5 wt. %, or at most about 2 wt. %) of the solid weight of the dielectric film forming compositions described herein.

In some embodiments, the dielectric film forming compositions described herein can optionally contain at least one (e.g., two, three, or four) surfactant. Examples of suitable surfactants include, but are not limited to, the surfactants described in JP-A-62-36663, JP-A-61-226746, JP-A-61-226745, JP-A-62-170950, JP-A-63-34540, JP-A-7-230165, JP-A-8-62834, JP-A-9-54432 and JP-A-9-5988, the entire contents of which are hereby incorporated by reference.

In some embodiments, the amount of the surfactant is at least about 0.005 wt. % (e.g., at least about 0.01 wt. % or at least about 0.1 wt. %) and/or at most about 1 wt. % (e.g., at most about 0.5 wt. % or at most about 0.2 wt. %) of the solid weight of the dielectric film forming compositions described herein.

In some embodiments, the dielectric film forming compositions described herein can optionally contain at least one (e.g., two, three, or four) corrosion inhibitor.

Examples of suitable corrosion inhibitors include triazole compounds, imidazole compounds and tetrazole compounds. Triazole compounds can include triazoles, benzotriazoles, substituted triazoles, and substituted benzotriazoles. The dielectric film forming compositions comprising corrosion inhibitors prevent corrosion and discoloration of copper or copper alloy when the photosensitive layer used on top of the copper or copper alloy. The corrosion inhibitor additive plays a significant role in improving HAST stability of TEG chip by effectively binding to the copper.

Examples of tetrazole compounds include 1-H-tetrazole, 5-methyl-1H-tetrazole, 5-phenyl-1H-tetrazole, 5-(ethylthio)-1H-tetrazole, 5-(benzylthio)-1H-tetrazole, ethyl 1H-tetrazole-5-acetate, ethyl 1H-tetrazole-5-carboxylate, 5-amino-1H-tetrazole, 1-phenyl-5-mercapto-1H-tetrazole, 5,5′-bis-1H-tetrazole, 1-methyl-5-ethyltetrazole, 1-methyl-5-mercaptotetrazole, 1-carboxymethyl-5-mercaptotetrazole, 5-amino-1H-tetrazole, 1-methyl-1H-tetrazole and the like.

Examples of triazole compounds include, but are not limited to, 1,2,4-triazole, 1,2,3-triazole, or triazoles substituted with substituents such as C₁-C₈ alkyl (e.g., 5-methyltriazole), amino, thiol, mercapto, imino, carboxy and nitro groups.

Further examples of triazole include 1,2,4-triazole, 1,2,3-triazole, 5-methyl-1,2,4-triazole, 3-amino-5-mercapto-1,2,4-triazole, 1-amino-1,2,3-triazole, 1-amino-5-methyl-1,2,3-triazole, 3-amino-1,2,4-triazole, 3-mercapto-1,2,4-triazole, 3-isopropyl-1,2,4-triazole, and the like.

Examples of benzotriazole of include 1-H benzotriazole, tolyltriazole, 5-phenyl-benzotriazole, 5-nitro-benzotriazole, hydroxybenzotriazole, 2-(5-amino-pentyl)-benzotriazole, 5-phenylthiol-benzotriazole, 5-methyl-1H-benzotriazole, 4-methyl-1H-benzotriazole, 4-carboxy-1H-benzotriazole, 5-carboxy-1H-benzotriazole, and the like. Examples of benzotriazole include 2-hydroxy-5-acrylyloxyphenyl-2H-benzotriazoles, 2-(5-methyl-2-hydroxyphenyl)benzotriazole, 2-(3-t-butyl-phenyl) 5-methyl-2-hydroxy-benzotriazole, 2-(3,5-di-t-amyl-2-hydroxyphenyl)benzotriazole, 2-hydroxy-3-chloro-5-acrylyloxyphenyl-2H-benzotriazoles and the like.

Examples of imidazole include, but are not limited to, 2-alkyl-4-methyl imidazole, 2-phenyl-4-alkyl imidazole, 2-methyl-4 (5)-nitroimidazole, 5-methyl-4-nitroimidazole, 4-Imidazolemethanol hydrochloride, and 2-mercapto-1-methylimidazole.

The amount of the optional corrosion inhibitor, if employed, is at least about 0.1 wt. % (e.g., at least about 0.2 wt. % or at least about 0.5 wt. %) and/or at most about 3.0 wt. % (e.g., at most about 2.0 wt. % or at most about 1.0 wt. %) of the solid weight of the dielectric film forming compositions described herein. If the amount of corrosion inhibitor is more than the range, the storage stability is reduced, and if the amount of corrosion inhibitor is less than the above range, voids between the copper or copper alloy surface is likely to occur.

In some embodiments, the dielectric film-forming compositions described herein include other optional components, such as one or more (e.g., two, three, or four) dyes, pigments, plasticizers, or antioxidants. Examples of such components have been described, e.g., in U.S. Application Publication No. 2022/0127459, the entire contents of which are hereby incorporated by reference.

In some embodiments, the dielectric film-forming compositions described herein are substantially fluorine-free compositions wherein the fully imidized polyimides, solubility switching compounds, photoinitiators, sensitizers, adhesion promoters, surfactants, solvents, corrosion inhibitors and additives are substantially fluorine free. In another embodiments, the dielectric film-forming compositions described herein are substantially free of per- and polyfluoroalkyl substances (PFAS). As such, the fully imidized polyimides, solubility switching compounds, photoinitiators, sensitizers, adhesion promoters, surfactants, solvents, corrosion inhibitors and additives are all free of per- and polyfluoroalkyl substances (PFAS). In some embodiments, the dielectric film-forming compositions described herein are substantially halogen free wherein the fully imidized polyimides, solubility switching compounds, photoinitiators, sensitizers, adhesion promoters, surfactants, solvents, corrosion inhibitors and additives are all substantially halogen free.

In some embodiments, a dielectric film can be prepared from a dielectric film forming composition described herein by a method including the steps of: (a) coating the dielectric film forming composition described herein on a substrate (e.g. a semiconductor substrate) to form a dielectric film; and (b) optionally baking the film at an elevated temperature (e.g., from about 50° C. to about 150° C.) for a period of time (e.g., from about 20 seconds to about 600 seconds).

Coating methods for preparation of the dielectric film include, but are not limited to, (1) spin coating, (2) spray coating, (3) roll coating, (4) rod coating, (5) rotation coating, (6) slit coating, (7) compression coating, (8) curtain coating, (9) die coating, (10) wire bar coating, (11) knife coating and (12) lamination of dry film. In case of coating methods (1)-(11), the dielectric film forming composition is typically provided in the form of a solution. One skilled in the art would choose the appropriate solvent type and solvent concentration based on the coating type.

Substrates can have circular, square or rectangular shapes such as wafers or panels in various dimensions. Examples of suitable substrates are epoxy molded compound (EMC), silicon, glass, copper, stainless steel, copper cladded laminate (CCL), aluminum, silicon oxide and silicon nitride. Substrates can be flexible such as polyimide, PEEK, polycarbonate, and polyester films. Substrates can have surface mounted or embedded chips, dyes, or packages. Substrates can be sputtered or pre-coated with a combination of seed layer and passivation layer. In some embodiments, the substrates mentioned herein can be a semiconductor substrate. As used herein, a semiconductor substrate is a substrate (e.g., a silicon or copper substrate or wafer) that becomes a part of a final electronic device.

The thickness of the dielectric film of this disclosure is not particularly limited. In some embodiments, the dielectric film has a film thickness of at least about 1 micron (e.g., at least about 2 microns, at least about 3 microns, at least about 4 microns, at least about 5 microns, at least about 6 microns, at least about 8 microns, at least about 10 microns, at least about 15 microns, at least about 20 microns, or at least about 25 microns) and/or at most about 100 microns (e.g., at most about 90 microns, at most about 80 microns, at most about 70 microns at most about 60 microns, at most about 50 microns, at most about 40 microns, or at most about 30 microns). In some embodiments, the thickness of the dielectric film is less than about 5 microns (e.g., less than about 4.5 microns, less than about 4.0 microns, less than about 3.5 microns, less than about 3.0 microns, less than about 2.5 microns, or less than about 2.0 microns). In some embodiments, when the dielectric film forming composition is photosensitive, the method to prepare a patterned photosensitive dielectric film includes converting the photosensitive dielectric film into a patterned dielectric film by a lithographic method. In such cases, the conversion can include exposing the photosensitive dielectric film to high energy radiation (such as electron beams, ultraviolet light, and X-ray) using a patterned mask.

After the exposure, the dielectric film can be heat treated from at least about 50° C. (e.g., at least about 55° C., at least about 60° C., or at least about 65° C.) to at most about 100° C. (e.g., at most about 95° C., or at most about 90° C., at most about 85° C., at most about 80° C., at most about 75° C., or at most about 70° C.) for at least about 60 seconds (e.g., at least about 65 seconds, or at least about 70 seconds) to at most about 240 seconds (e.g., at most about 180 seconds, at most about 120 seconds or at most about 90 seconds). The heat treatment is usually accomplished by use of a hot plate or oven.

After the exposure and heat treatment, the dielectric film can be developed to remove unexposed portions by using a developer to form openings or a relief image on the substrate. Development can be carried out by, for example, an immersion method or a spraying method. Microholes and fine lines can be generated in the dielectric film on the laminated substrate after development.

In some embodiments, the dielectric film can be developed by use of an organic developer. Examples of such developers can include, but are not limited to, suitable organic solvents such as gamma-butyrolactone (GBL), gamma-valerolactone, cyrene, 2-methyl tetrahydrofuran, dimethyl sulfoxide (DMSO), N,N-diethylacetamide, methyl ethyl ketone (MEK), methyl isobutyl ketone (MIBK), 2-heptanone, cyclopentanone (CP), cyclohexanone, n-butyl acetate (nBA), propylene glycol methyl ether acetate (PGMEA), propylene glycol methyl ether (PGME), ethyl lactate (EL), propyl lactate, 3-methyl-3-methoxybutanol, tetralin, isophorone, ethylene glycol monobutyl ether, diethylene glycol monoethyl ether, diethylene glycol monoethyl ether acetate, diethylene glycol dimethyl ether, diethylene glycol methylethyl ether, triethylene glycol monoethyl ether, dipropylene glycol monomethyl ether, methyl 3-methoxypropionate, ethyl 3-ethoxypropionate, diethyl malonate, ethylene glycol, 1,4:3,6-dianhydrosorbitol, isosorbide dimethyl ether, 1,4:3,6-dianhydrosorbitol 2,5-diethyl ether (2,5-diethylisosorbide) and mixtures thereof. Preferred developers are gamma-valerolactone, cyrene, 2-methyl tetrahydrofuran, gamma-butyrolactone (GBL), cyclopentanone (CP), cyclohexanone, ethyl lactate (EL), n-butyl acetate (nBA) and dimethylsulfoxide (DMSO). These developers can be used individually or in combination of two or more to optimize the image quality for the composition and lithographic method.

In some embodiments, the dielectric film can be developed by using an aqueous developer. When the developer is an aqueous solution, it preferably contains one or more aqueous bases. Examples of suitable bases include, but are not limited to, inorganic alkalis (e.g., potassium hydroxide, sodium hydroxide), primary amines (e.g., ethylamine, n-propylamine), secondary amines (e.g., diethylamine, di-n-propylamine), tertiary amines (e.g., triethylamine), alcoholamines (e.g., triethanolamine), quaternary ammonium hydroxides (e.g., tetramethylammonium hydroxide or tetraethylammonium hydroxide), and mixtures thereof. The concentration of the base employed will vary depending on, e.g., the base solubility of the polymer employed. The most preferred aqueous developers are those containing tetramethylammonium hydroxide (TMAH). Suitable concentrations of TMAH range from about 1% to about 5%.

In some embodiments, after the development by an organic developer, an optional rinse treatment can be carried out with an organic rinse solvent to remove residues. Suitable examples of organic rinse solvents include, but are not limited to, alcohols such as isopropyl alcohol, methyl isobutyl carbinol (MIBC), propylene glycol monomethyl ether (PGME), and amyl alcohol; esters such as n-butyl acetate (nBA), ethyl lactate (EL) and propylene glycol monomethyl ether acetate (PGMEA); ketnoes such as methyl ethyl ketone, and mixtures thereof.

In some embodiments, after the development step or the optional rinse treatment step, an optional baking step (e.g., post development bake) can be carried out at a temperature ranging from at least about 120° C. (e.g., at least about 130° C., at least about 140° C., at least about 150° C., at least about 160° C., at least about 170° C., or at least about 180° C.) to at most about 250° C. (e.g., at most about 240° C., at most about 230° C., at most about 220° C., at most about 210° C., at most about 200° C. or at most about 190° C.). The baking time is at least about 5 minutes (e.g., at least about 10 minutes, at least about 20 minutes, at least about 30 minutes, at least about 40 minutes, at least about 50 minutes, or at least about 60 minutes) and/or at most about 5 hours (e.g., at most about 4 hours, at most about 3 hours, at most about 2 hours, or at most about 1.5 hours). This baking step can remove residual solvent from the remaining dielectric film and can further crosslink the remaining dielectric film. Post development bake can be done in air or preferably, under a blanket of nitrogen and may be carried out by any suitable heating means.

In some embodiments, the patterned dielectric film includes at least one element having a feature size of at most about 10 microns (e.g., at most about 9 microns, at most about 8 microns, at most about 7 microns, at most about 6 microns, at most about 5 microns, at most about 4 microns, at most about 3 microns, at most about 2 microns, or at most about 1 micron). One important embodiment of this disclosure is that the dielectric films prepared from the dielectric film forming composition described herein can produce a patterned film with a feature size of at most about 3 microns (e.g., at most 2 microns or at most 1 micron) by a laser ablation method.

In some embodiments, the embodiment ratio (ratio of height to width) of a feature (e.g., the smallest feature) of the patterned dielectric film of this disclosure is at least about ⅓ (e.g., at least about ½, at least about 1/1, at least about 2/1, at least about 3/1, at least about 4/1, or at least about 5/1).

In some embodiments (e.g., when the dielectric film forming composition is non-photosensitive), the method to prepare a patterned dielectric film include converting the dielectric film into the patterned dielectric film by a laser ablation technique. Direct laser ablation method with an excimer laser beam is generally a dry, one step material removal to form openings (or patterns) in the dielectric film. In some embodiments, the wavelength of the laser is 640 nm or less (e.g., 157 nm, 193 nm, 248 nm, 308 nm, 351 nm, 405 nm, 445 nm, 470 nm, 520 nm, 528 nm, 555 nm, or 640 nm). Examples of suitable laser ablation methods include, but are not limited to, the methods described in US Patent Nos 7,598, 167, 6,667,551, and 6,114,240, the contents of which are hereby incorporated by reference.

In embodiments when the dielectric film forming composition is non-photosensitive, the composition can be used to form the bottom layer in a bilayer photoresist. In such embodiment, the top layer of the bilayer photoresist can be a photosensitive layer and can be patterned upon exposure to high energy radiation. The pattern in the top layer can be transferred to the bottom dielectric layer (e.g., by etching). The top layer can then be removed (e.g., by using a wet chemical etching method) to form a patterned dielectric film.

In some embodiments, this disclosure features a method for depositing a metal layer (e.g., to create an embedded copper trace structure) that includes the steps of: (a) forming a patterned dielectric film having openings; and d) depositing a metal layer (e.g., an electrically conductive metal layer) in at least one opening in the patterned dielectric film. For example, the method can include the steps of: (a) depositing a dielectric film forming composition described herein on a substrate (e.g., a semiconductor substrate) to form a dielectric film; (b) exposing the dielectric film to a source of radiation or heat or a combination thereof (e.g., through a mask); (c) patterning the dielectric film to form a patterned dielectric film having openings; and (d) depositing a metal layer (e.g., an electrically conductive metal layer) in at least one opening in the patterned dielectric film. In some embodiments, steps (a)-(d) can be repeated one or more (e.g., two, three, or four) times.

In some embodiments, this disclosure features a method to deposit a metal layer (e.g., an electrically conductive copper layer to create an embedded copper trace structure) on a semiconductor substrate. In some embodiment, to achieve this, a seed layer conformal to the patterned dielectric film is first deposited on the patterned dielectric film (e.g., outside the openings in the film). Seed layer can contain a barrier layer and a metal seeding layer (e.g., a copper seeding layer). In some embodiments, the barrier layer is prepared by using materials capable of preventing diffusion of an electrically conductive metal (e.g., copper) through the dielectric layer. Suitable materials that can be used for the barrier layer include, but are not limited to, tantalum (Ta), titanium (Ti), tantalum nitride (TiN), tungsten nitride (WN), and Ta/TaN. A suitable method of forming the barrier layer is sputtering (e.g., PVD or physical vapor deposition). Sputtering deposition has some advantages as a metal deposition technique because it can be used to deposit many conductive materials, at high deposition rates, with good uniformity and low cost of ownership. Conventional sputtering fill produces relatively poor results for deeper, narrower (high-embodiment-ratio) features. The fill factor by sputtering deposition has been improved by collimating the sputtered flux. Typically, this is achieved by inserting between the target and substrate a collimator plate having an array of hexagonal cells.

The next step in this method is metal seeding deposition. A thin metal (e.g., an electrically conductive metal such as copper) seeding layer can be formed on top of the barrier layer in order to improve the deposition of the metal layer (e.g., a copper layer) formed in the succeeding step.

The next step in this method is depositing an electrically conductive metal layer (e.g., a copper layer) on top of the metal seeding layer in the openings of the patterned dielectric film wherein the metal layer is sufficiently thick to fill the openings in the patterned dielectric film. The metal layer to fill the openings in the patterned dielectric film can be deposited by plating (such as electroless or electrolytic plating), sputtering, plasma vapor deposition (PVD), and chemical vapor deposition (CVD). Electrochemical deposition is generally a preferred method to apply copper since it is more economical than other deposition methods and can flawlessly fill copper into the interconnect features. Copper deposition methods generally should meet the stringent requirements of the semiconductor industry. For example, copper deposits should be uniform and capable of flawlessly filling the small interconnect features of the device, for example, with openings of 100 nm or smaller. This technique has been described, e.g., in U.S. Pat. Nos. 5,891,804, 6,399,486, and 7,303,992, the contents of which are hereby incorporated by reference.

In some embodiments, the method of depositing an electrically conductive metal layer further includes removing overburden of the electrically conductive metal or removing the seed layer (e.g., the barrier layer and the metal seeding layer). In some embodiments, the overburden of the electrically conductive metal layer (e.g., a copper layer) is at most about 3 microns (e.g., at most about 2.8 microns, at most about 2.6 microns, at most about 2.4 microns, at most about 2.2 microns, at most about 2.0 microns, or at most about 1.8 microns) and at least about 0.4 micron (e.g., at least about 0.6 micron, at least about 0.8 micron, at least about 1.0 micron, at least about 1.2 micron, at least about 1.4 micron, or at least about 1.6 microns). Examples of copper etchants for removing copper overburden include an aqueous solution containing cupric chloride and hydrochloric acid or an aqueous mixture of ferric nitrate and hydrochloric acid. Examples of other suitable copper etchants include, but are not limited to, the copper etchants described in U.S. Pat. Nos. 4,784,785, 3,361,674, 3,816,306, 5,524,780, 5,650,249, 5,431,776, and 5,248,398, and US Application Publication No. 2017/0175274, the contents of which are hereby incorporated by reference.

In some embodiments the disclosure describes methods for surrounding a metal structured substrate containing conducting metal (e.g., copper) wire structures forming a network of lines and interconnects with the dielectric film described herein. Such methods can be performed, for example, by:
a) providing a substrate containing conducting metal wire structures that form a network of lines and interconnects on the substrate.
b) depositing a dielectric film forming composition described herein on the substrate to form a dielectric film (e.g., that surrounds the conducting metal lines and interconnects); and
c) exposing the dielectric film to a source of radiation or heat or a combination of radiation and heat (with or without a mask).

The above steps can be repeated multiple times (e.g., two, three, or four times) to form a complex multi-layered three-dimensional object.

In some embodiments, this disclosure features a method of preparing a dry film structure. The method includes:
a) coating a carrier substrate (e.g., a substrate including at least one polymeric or plastic film) with a dielectric film forming composition described herein.
b) drying the coated dielectric film forming composition to form a dielectric layer (e.g., a photosensitive, dielectric layer); and
c) optionally, applying a protective layer to the dry film structure.

In some embodiments, the carrier substrate is a single or multiple layer polymeric or plastic film, which can include one or more polymers (e.g., polyethylene terephthalate). In some embodiments, the carrier substrate has excellent optical transparency, and it is substantially transparent to actinic irradiation used to form a relief pattern in the polymer layer. The thickness of the carrier substrate is preferably in the range of at least about 10 μm (e.g., at least about 15 μm, at least about 20 μm, at least about 30 μm, at least about 40 μm, at least about 50 μm, or at least about 60 μm) to at most about 150 μm (e.g., at most about 140 μm, at most about 120 μm, at most about 100 μm, at most about 90 μm, at most about 80 μm, or at most about 70 μm).

In some embodiments, the protective layer is a single or multiple layer film, which can include one or more polymers (e.g., polyethylene or polypropylene). Examples of carrier substrates and protective layers have been described in, e.g., U.S. Application Publication No. 2016/0313642, the contents of which are hereby incorporated by reference.

When dielectric layers of the disclosure are present in a microelectronic device, the dielectric layer imparts good reliability to the device. Reliability is the probability that an electronic component will perform the required function under stressed conditions for a designated period. Preconditioning, Temperature Humidity Bias (THB), Biased Humidity Stress Test (bHAST), Unbiased HAST (uHAST), High Temp Storage (HTS) are commonly used stress test applied for semiconductor packaging materials. Reliability is measured as the proportion of devices used from time zero that will not have failed by a given time ‘t’.

The Highly Accelerated Stress Test (HAST) combines high temperature, high humidity, high pressure, and time to measure component reliability with or without electrical bias. In a controlled environment, HAST testing accelerates the stresses of the more traditional tests. It essentially functions as a corrosion failure test. Corrosion type failures are accelerated, uncovering flaws such as in packaging seals, materials, and joints over a shorter period of time.

Biased Highly Accelerated Stress Tests (bHAST) utilize the same variables (high pressure, high temperature and time) as HAST Tests, but add a voltage bias. The goal of BHAST testing is to accelerate corrosion within the device, thereby speeding up the test period. In unbiased HAST tests, humidity accelerates failure mechanisms related the presence of moisture for non-hermetic packages. Biased voltage under high humidity causes galvanic and electrochemical corrosion in non-hermitic packages in biased Humidity Stress Test (bHAST). For advanced/emerging package technologies, board level reliability (BLR) testing is conducted to determine the solder joint interconnect reliability using daisy-chained test vehicles. Failure analysis is conducted on failed samples to determine the cause.

As an accelerated version of the traditional non-condensing THB (temperature humidity bias) test, the HAST test has the advantage of adding high pressure and higher temperatures (up to 149° C.) to accelerate temperature and moisture induced failures in roughly one-tenth the time of THB. HAST and BHAST testing is usually run at 130° C./85% RH, but the conditions can also vary.

Typical HAST test conditions consist of 110 or 130° C. temperature, and 85% RH humidity and a test run time of 96 hours or 200 hours. Once the highly accelerated stress test is completed, tested samples are analyzed by microscope and SEM for changes happen during HAST conditions. HAST testing generally follows JEDEC spec JESD22 A110, “Highly Accelerated Temperature and Humidity Stress Test (HAST).” Biased Humidity Stress Test (bHAST) is the most sensitive stress test for reliability of a microelectronic device by using an organic dielectric film composition. Examples of bHAST methods used in evaluation of semiconductor devices have been described in, e.g., U.S. Pat. No. 9,874,813 and US patent application 2021/0272898 and the contents of which are hereby incorporated by reference.

TEG (Test Element Group) wafer with Cu post (pillar) plating was used for evaluation of wafer for such as material development, package stability under HAST conditions by inspection method. Examples of TEG wafers used in evaluation of semiconductor devices have been described in, e.g., U.S. Pat. Nos. 8,237,450 and 9,082,708, the contents of which are hereby incorporated by reference.

In some embodiments, the dielectric film of the dry film structure can be delaminated from carrier layer as a self-standing dielectric film. A self-standing dielectric film is a film that can maintain its physical integrity without using any support layer such as a carrier layer. In some embodiments, the self-standing dielectric film is not crosslinked or cured and can include the components of the dielectric film forming composition described above except for the solvent.

In some embodiments, the dielectric loss tangent or dissipation factor of the dielectric film prepared from dielectric film forming composition described herein measured at 10 GHZ, 15 GHZ, and/or 35 GHz is in the range of from at least about 0.001 (e.g., at least about 0.002, at least about 0.003, at least about 0.004, at least about 0.005, at least about 0.01, or at least about 0.05) to at most about 0.1 (e.g., at most about 0.08, at most about 0.06, at most about 0.05, at most about 0.04, at most about 0.02, at most about 0.01, at most about 0.008, at most about 0.006, or at most about 0.005).

In some embodiments, the dielectric film of the dry film structure can be laminated to a substrate (e.g., a semiconductor substrate such as a wafer) using a vacuum laminator at about 50° C. to about 140° C. after pre-laminating of the dielectric film of the dry film structure with a plane compression method or a hot roll compression method. When the hot roll lamination is employed, the dry film structure can be placed into a hot roll laminator, the optional protective layer can be peeled away from the dielectric film/carrier substrate, and the dielectric film can be brought into contact with and laminated to a substrate using rollers with heat and pressure to form an article containing the substrate, the dielectric film, and the carrier substrate. The dielectric film can then be exposed to a source of radiation or heat (e.g., through the carrier substrate) to form a crosslinked dielectric film. In some embodiments, the carrier substrate can be removed before exposing the dielectric film to a source of radiation or heat.

Some embodiments of this disclosure describe a method of generating a planarizing dielectric film on a substrate with copper pattern. In some embodiments, the method includes depositing a dielectric film forming composition onto a substrate with copper pattern to form a dielectric film. In some embodiments, the method includes steps of:
a. providing a dielectric film forming composition of this disclosure, and
b. depositing the dielectric film forming composition onto a substrate having a copper pattern to form a dielectric film, wherein the difference in the highest and lowest points on a surface of the dielectric film is at most about 2 microns (e.g., at most about 1.5 microns, at most about 1 micron, or at most about 0.5 micron).

In some embodiments, this disclosure features an article (or a three-dimensional object) containing at least one patterned dielectric film formed by a method described herein. Examples of such articles include a semiconductor substrate, a flexible film for electronics, a wire isolation, a wire coating, a wire enamel, and an inked substrate. In some embodiments, this disclosure features semiconductor devices that include one or more of these articles. Examples of semiconductor devices that can be made from such articles include an integrated circuit, a light emitting diode, a solar cell, and a transistor.

The present disclosure is illustrated in more detail with reference to the following examples, which are for illustrative purposes and should not be construed as limiting the scope of the present disclosure.

### EXAMPLES

### Synthesis Example 1: Preparation of Fully Imidized Polyimide Polymer (PI-I)

Solid 4,4′-oxidiphthalic anhydride (ODPA) (122.22 g) is charged to a solution of 1-(4-aminophenyl)-1,3,3-trimethylindan-5-amine[also known as 4,4′-[1,4-phenylene-bis(1-methylethylidene)]bisaniline (DAPI)](53.28 g) and 2,2-Bis[4-(4-aminophenoxy)phenyl]propane (BAPP) (41.05 g) and 6-amino-3-(3′-amino-4′-hydroxyphenyl)-1,1,3-trimethyl-2,3-dihydro-1H-inden-5-ol (Indane bis-o-aminophenol) (29.84 g) in NMP (N-methyl pyrrolidone) (640 g) at 25° C. Additional NMP (100 g) is used to rinse the dianhydride into the solution. The reaction temperature is increased to 40° C. and the mixture is allowed to react for 3 hours. Next, acetic anhydride (89.8 g) and pyridine (17.4 g) are added, the reaction temperature is increased to 100° C., and the mixture was allowed to react for 12 hours.

The solution is diluted with 300 g of tetrahydrofuran (THF). Then, the solution is precipitated into 8 L of distilled water. After filtration, the wet cake is dried in air. The crude polymer is dissolved in 500 g of THF and precipitated into 8 L of distilled water. After filtration, the wet cake is dried in air and then under vacuum at 60° C. for 12 h for complete removal of moisture. The weight average molecular weight (Mw) is measured by GPC.

### Synthesis Example 2: Preparation of Fully Imidized Polyimide Polymer (PI-II)

Solid 4,4′-oxidiphthalic anhydride (ODPA) (122.22 g) is charged to a solution of DAPI (53.28 g) and BAPP (41.05 g) and Indane bis-o-aminophenol (29.84 g) in NMP (640 g) at 25° C. Additional NMP (100 g) is used to rinse the dianhydride into the solution. The reaction temperature is increased to 40° C. and the mixture is allowed to react for 3 hours. Then, methacrylic anhydride (30.8 g) and pyridine (15.8 g) are added and stirred for 2 h. Next, acetic anhydride (89.8 g) and pyridine (17.4 g) are added, the reaction temperature is increased to 100° C., and the mixture is allowed to react for 12 hours.

The solution is diluted with 300 g of tetrahydrofuran (THF). Then, the solution is precipitated into 8 L of distilled water. After filtration, the wet cake is dried in air. The crude polymer is dissolved in 500 g of THF and precipitated into 8 L of distilled water. After filtration, the wet cake is dried in air and then under vacuum at 60° C. for 12 h for complete removal of moisture. The weight average molecular weight (Mw) is measured by GPC.

### Synthesis Example 3: Preparation of Fully Imidized Polyimide (PI-III)

Solid 2,2′,3,3′-benzophenone tetracarboxylic dianhydride (BTDA) (127.3 g) is charged to a solution of DAPI (79.91 g) and Indane bis-o-aminophenol (29.84 g) in NMP (445 g) at 25° C. Additional NMP (100 g) is used to rinse the dianhydride into the solution. The reaction temperature is increased to 40° C. and the mixture is allowed to react for 3 hours. To perform the end-capping reaction, 2.97 grams of 4-methacryloxyethyl trimellitic anhydride) (META) and 2.0 grams of pyridine are charged to flask. The mixture is agitated at 60 degrees centigrade for 3 hours.

Next, acetic anhydride (60.4 g) and pyridine (23.43 g) is added, the reaction temperature was increased to 100° C., and the mixture is allowed to react for 12 hours. The processing method is followed by Example 1 and the weight average molecular weight (Mw) is measured by GPC.

The following designations are to be used with reference to the Photosensitive Composition Examples set forth below.
(B) multifunctional(meth)acrylate crosslinker
B-1: tetra(ethylene glycol) diacrylate, D048 (trade name, available from Green Chemical, Korea)
B-2: penta erythritol triacrylate, SR295 (trade name, available from Sartomer)
B-3: hexanediol diacrylate SR238 (trade name, available from Sartomer)
B-4: tricyclodecane dimethanol diacrylate SR833S (trade name, available from Sartomer)
B-5:1,6-bisphenol A (EO) 2 diacrylate (manufactured by Sigma Aldrich Corp.)
B-6:2-(tricyclo[5.2.1.02,6]dec-3-en-8-yloxy)ethyl acrylate (manufactured by Sigma Aldrich Corp.)
B-7: tris(2-hydroxy ethyl) isocyanurate triacrylate (manufactured by Tokyo Chemical Industry Co., Ltd.)
B-8:1,9-Nonanediol diacrylate (manufactured by Tokyo Chemical Industry Co., Ltd.)
B-9:1,10-decyldiol diacrylate SR595 (trade name, available from Sartomer)
(C) Photo-radical polymerization initiator
C-1: NCI-831 (trade name, available from ADEKA corporation),
C-2: IRGACURE OXE 01 (manufactured by BASF)
C3: IRGACURE OXE 02 (manufactured by BASF)
C4: KEYCURE VIS-831 (Titanium (4+) 2,4-cyclopentadienide 1-(2,4-difluorophenyl)-1H-pyrrol-3-ide (1:2:2) (manufactured by KING BROTHER CHEM CO., LTD)
(D) Adhesion promoter
D-1: gamma-glycidoxypropyltrimethoxysilane (Available from Gelest Corporation) D-2: Gamma-Glycidoxypropyltrimethoxysilane or SilQuest A-187 (Available from Gelest Corporation)
D-3:3-(Trimethoxysilyl) propyl methacrylate (Available from Gelest Corporation)
(E) Polymerization inhibitor
E-1: monomethyl ether hydroquinone (manufactured by Tokyo Chemical Industry Co., Ltd.)
E-2: Parabenzoquinone (manufactured by Tokyo Chemical Industry Co., Ltd.)
E-3: t-Butylcatechol (manufactured by Tokyo Chemical Industry Co., Ltd.)
(F) Copper corrosion inhibitor
F-1:5-methyl benzotriazole (manufactured by Tokyo Chemical Industry Co., Ltd.)
F-2:2-hydroxy-5-acrylyloxyphenyl-2H-benzotriazole (manufactured by Tokyo Chemical Industry Co., Ltd.)
F-3:1H Tetrazole (manufactured by Tokyo Chemical Industry Co., Ltd.)
F-4:5-Phenyl 1H Tetrazole (manufactured by Tokyo Chemical Industry Co., Ltd.)
F-5: Ethyl 1H-tetrazole-5-acetate (manufactured by Tokyo Chemical Industry Co., Ltd.)
F-6: Ethyl 1H-tetrazole-5-carboxylate (manufactured by Tokyo Chemical Industry Co., Ltd.)
F-7:3-Amino-1,2,4-triazole (manufactured by Tokyo Chemical Industry Co., Ltd.)
F-8:3,5-Diamino-1,2,4-triazole (manufactured by Tokyo Chemical Industry Co., Ltd.)
(G) Surfactant
G-1: PolyFox 6320 (available from OMNOVA Solutions) in GBL
G-2:0.5 wt % solution of PolyFox 6320 (available from OMNOVA Solutions) in propylene carbonate
G-3: Troysol S366 (available from Troy Corp. Inc) in 0.5% GBL
(H) Solvent
H-1: gamma-Butyrolactone (manufactured by Eastman)
H-2: Cyclopentanone (manufactured by Solvay)
H-3: Propylene Carbonate (manufactured by Huntsman)
H-4: Dimethyl sulfoxide (manufactured by Sigma Aldrich Corp.)
H-5: N-methyl-2-pyrrolidone (manufactured by Ashland
(I) Additive
I-1:50% solution of XU 378 in cyclopentanone (manufactured by Huntsman)
I-2:50% solution of 2,2-bis(4-cyanatophenyl) propane in cyclopentanone (manufactured by Tokyo Chemical Industry Co., Ltd.)

### Photosensitive Composition Example 1

A photosensitive composition (FE-1) is prepared by using 80 g of polymer solution (PI-I), 14.69 g of GBL (H-1), 1.42 g of a 0.5 wt. % solution of PolyFox 6320 (available from OMNOVA Solutions) in GBL (G-1), 0.71 g of 3-(Trimethoxysilyl) propyl methacrylate (D-3), 0.71 g of NCI-831E (trade name, available from ADEKA corporation), (C-1), 0.05 g of para-benzoquinone (E-2), 8.00 g of tetra(ethylene glycol) diacrylate (B-1), and 2.67 g of penta erythritol triacrylate (B-2). After being stirred mechanically for 24 hours, the solution is filtered by using a 0.2 microns filter.

### Photosensitive Composition Example 2

A photosensitive composition (FE-2) is prepared by using 100 parts of a 32.46 percent solution of a polyimide polymer (PI-II), 93.2 parts of cyclopentanone (manufactured by Solvay) (H-2), 27.5 parts of gamma-butyrolactone (manufactured by Eastman) (H-1),5.9 parts of PolyFox 6320 (available from OMNOVA Solutions) in GBL (G-1), 5 parts of 3-(trimethoxysilyl) propyl methacrylate (available from Gelest Corporation) (D-3), 3.0 part of IRGACURE OXE 01 (manufactured by BASF) (C-2), 0.1 parts of t-Butylcatechol (manufactured by Tokyo Chemical Industry Co., Ltd.) (E-3), 32.5 parts of tetra(ethylene glycol) diacrylate, D048 (trade name, available from Green Chemical, Korea), 12.5 parts of pentaerythritol triacrylate (SR295, trade name, available from Sartomer) (B-2), 5.0 parts of 2-(tricyclo[5.2.1.02,6]dec-3-en-8-yloxy)ethyl acrylate (manufactured by Sigma Aldrich Corp) (B-6) and 0.62 parts of 5-methyl benzotriazole (manufactured by Tokyo Chemical Industry Co., Ltd.) (F-1). After being stirred mechanically for 24 hours, the solution is filtered by using a 0.2 microns filter (Ultradyne from Meissner Corporation, cat #CLTM0.2-552).

### Photosensitive Composition Example 3

A photosensitive composition (FE-3) is prepared by using 100 parts of a 29.19% solution of polyimide polymer (PI-III), 9.5 parts of cyclopentanone (manufactured by Solvay) (H-2), 142 parts of propylene Carbonate (manufactured by Huntsman) (H-3), 6.0 parts of 0.5 wt. % solution of PolyFox 6320 (available from OMNOVA Solutions) in propylene carbonate, (G-2), 5.0 parts of 3-(trimethoxysilyl) propyl methacrylate (Available from Gelest Corporation) (D-3), 3.0 parts of IRGACURE OXE 01 (manufactured by BASF) (C-2), 0.2 parts of hydroquinone (E-1), 37.5 parts of tetra(ethylene glycol) diacrylate, D048 (trade name, available from Green Chemical, Korea) (B-1), 12.5 parts of tetra(ethylene glycol) diacrylate, D048 (trade name, available from Green Chemical, Korea) (B-2), 10.0 parts of 50% solution of 2,2-bis(4-cyanatophenyl) propane in cyclopentanone (manufactured by Tokyo Chemical Industry Co., Ltd.) (1-2) and 0.5 parts of 5-methyl benzotriazole (manufactured by Tokyo Chemical Industry Co., Ltd.) (F-1). After being stirred mechanically for 24 hours, the solution is filtered by using a 0.2 micron filter (Ultradyne from Meissner Corporation, cat #CLTM0.2-552).

### Photosensitive Composition Example 4

A photosensitive composition (FE-4) is prepared by using 100 parts of a 29.19% solution of polyimide polymer (PI-III), 9.5 parts of cyclopentanone (manufactured by Solvay) (H-2), 142 parts of propylene Carbonate (manufactured by Huntsman) (H-3), 2.0 parts by weights of Troysol S366 (available from Troy Corp. Inc) in 0.5% GBL, (G-3), 5.0 parts of 3-(trimethoxysilyl) propyl methacrylate (Available from Gelest Corporation) (D-3), 3.0 parts of IRGACURE OXE 01 (manufactured by BASF) (C-2), 0.2 parts of hydroquinone (E-1), 37.5 parts of tetra(ethylene glycol) diacrylate, D048 (trade name, available from Green Chemical, Korea) (B-1), 12.5 parts of tetra(ethylene glycol) diacrylate, D048 (trade name, available from Green Chemical, Korea) (B-2), 10.0 parts of 50% solution of 2,2-bis(4-cyanatophenyl) propane in cyclopentanone (manufactured by Tokyo Chemical Industry Co., Ltd.) (1-2) and 0.5 parts of 5-methyl benzotriazole (manufactured by Tokyo Chemical Industry Co., Ltd.) (F-1). After being stirred mechanically for 24 hours, the solution is filtered by using a 0.2 micron filter (Ultradyne from Meissner Corporation, cat #CLTM0.2-552).

### Lithographic Method Example 1

The photosensitive composition FE-1 is spin coated on a silicon wafer and baked at 95° C. for 6 minutes using a hot plate to form a coating with a thickness of 7.95 microns. The photosensitive polyimide film is exposed at various levels of exposure energy using a Cannon 4000 IE i-line stepper.

Unexposed portions are removed by using cyclopentanone as a developer (1×40 seconds of dynamic development), followed by rinsing the developed film with PGMEA for 15 seconds to form a pattern. A resolution of 4 microns at a photospeed of 200 mJ/cm² is achieved. The film thickness loss is 20%.

### General Procedure for Mechanical Properties Measurement of Film

A filtered polymer solution is applied via spin coating onto a silicon oxide wafer to obtain a film with a thickness of approximately 12.0 microns to 15.0 microns. The coating is dried on a hot plate oven at 90° C. for 10 minutes. The film is then exposed to 500 mJ/cm². Finally, the film is baked at 230° C. for 3 hours under vacuum using YES oven. The film is delaminated from silicon oxide layer by using 2% hydrofluoric acid solution and dried in air at 50° C. for 2 hours. After cooling to room temperature, the film is characterized by DMA for Tg measurement.

### Reliability Test Examples

The dielectric film forming composition of Example FE 1-3 are spin-coated at 1200 rpm onto a TEG chip with copper-plated line/space pattern ranging from 2/2 microns, 8/8 microns, 15/15 microns at 6-12 microns thickness and baked at 95 degrees centigrade for 5 minutes using a hot plate to form a coating with a thickness of about 13 microns. The dielectric film forming compositions are then blanket exposed at 500 m J/cm² by using an LED i-line exposure tool. The compositions are cured at 170-230 degrees centigrade for 3 hours in a YES oven.

What is claimed is:

1. A polyimide comprising the reaction product of components (a), (b), and (c), wherein components (a), (b), and (c), are:
(a) at least one indane bis-o-aminophenol selected from the group consisting of a diamine of Formula 1a 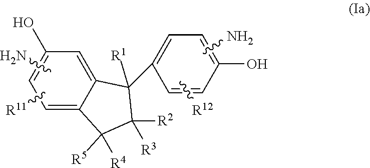
wherein each of R¹, R², R³, R⁴, and R⁵ independently, is a hydrogen atom, a substituted or unsubstituted C₁-C₁₂ alkyl, a partially halogen substituted or fully halogen substituted C₁-C₁₂ alkyl, a substituted or unsubstituted C₄-C₁₈ cycloalkyl, a substituted or unsubstituted C₆-C₂₂ aryl, or a substituted or unsubstituted C₅-C₂₂ heteroaryl; each of R¹¹ and R¹² is a hydrogen atom, a linear or branched C₁-C₄ alkyl, C₄-C₁₂ cycloalkyl, C₆-C₁₈ aryl, C₅-C₁₈ heteroaryl group, C₁-C₄ alkoxy group or a halogen atom,
(b) at least one other diamine; and
(c) at least one tetracarboxylic acid dianhydride.

2. A polyimide comprising the reaction product of components (a), (b), (c), and (d), wherein components (a), (b), (c), and (d) are:
(a) at least one diamine selected from the group consisting of a one indane bis-o-aminophenol of Formula (Ia) 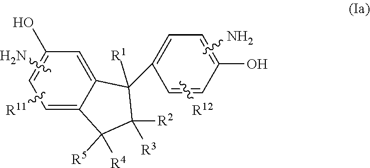
wherein each of R¹, R², R³, R⁴, and R⁵ independently, is a hydrogen atom, a substituted or unsubstituted C₁-C₁₂ alkyl, a partially halogen substituted or fully halogen substituted C₁-C₁₂ alkyl, a substituted or unsubstituted C₄-C₁₈ cycloalkyl, a substituted or unsubstituted C₆-C₂₂ aryl, or a substituted or unsubstituted C₅-C₂₂ heteroaryl; each of R¹¹ and R¹² is a hydrogen atom, a linear or branched C₁-C₄ alkyl, C₄-C₁₂ cycloalkyl, C₆-C₁₈ aryl, C₅-C₁₈ heteroaryl group, C₁-C₄ alkoxy group or a halogen atom,
(b) at least one other diamine
(c) at least one tetracarboxylic acid dianhydride, and
(d) at least one diamine, selected from the group consisting of a diamine of Structure (1a), wherein the phenolic hydroxyl groups are functionalized with reactive functional groups selected from substituted or unsubstituted linear alkenyl groups, substituted or unsubstituted linear alkynyl groups, and (meth)acryloyl groups.

3. A photosensitive composition, comprising:
(a) at least one polyimide of claim 1 or 2;
(b) at least one solubility switching compound comprising at least one functional group selected from the group consisting of a vinyl group, an allyl group, a vinyl ether group, a propenyl ether group, a (meth)acryloyl group, a SiH group, and a thiol group;
(c) at least one initiator, and
(d) at least one solvent.

4. The photosensitive composition of claim 3 wherein the composition further comprises at least one member selected from the group consisting of at least one plasticizer compound, at least one adhesion promoter, at least one surfactant, at least one filler, at least one pigment, at least one dye, and at least one metal-containing (meth)acrylate compound.

5. A process, comprising coating a substrate with the composition of claim 4 to form a coated substrate having a film on the substrate, and baking the coated substrate to form a coated substrate having a dried film

6. The process of claim 5, wherein the coated substrate is baked at a temperature from about 50 degrees centigrade to about 200 degrees centigrade.

7. The process of claim 6, further comprising exposing the dried film to radiation through a mask to form a coated substrate having a dried, pattern-wise exposed film.

8. The process of claim 7, further comprising baking the dried, pattern-wise exposed film at a temperature from about 50 degrees centigrade to about 150 degrees centigrade in a second baking step.

9. The process of claim 8, further comprising developing a portion of the dried, exposed film in a developer to produce a relief image on the substrate.

10. The process of claim 9, further comprising rinsing the relief image on the substrate with a solvent or a mixture of solvents.

11. The process of claim 10, further comprising baking the substrate having a relief image at a temperature from about 50 degrees centigrade to about 200 degrees centigrade in a third baking step.

12. An article formed by the process of claim 11, wherein the article is a semiconductor substrate, a flexible film for electronics, a wire isolation, a wire coating, a wire enamel, or an inked substrate.

13. A semiconductor device, comprising the article of claim 12.

14. The semiconductor device of claim 13, wherein the semiconductor device is an integrated circuit, a light emitting diode, a solar cell, or a transistor.

15. A dry film structure, comprising a carrier substrate, a protective layer, and a polymeric layer of claim 4 disposed between the carrier substrate and the protective layer.

16. A process, comprising:
(a) removing the protective layer from the dry film structure of claim 15; and
(b) applying the structure obtained in step (a) onto an electronic substrate to form a laminate.

17. The process of claim 16, further comprising removing the carrier substrate before or after exposing the polymeric layer.

18. The process of claim 17, further comprising removing unexposed portions in the polymeric layer by using a developer.

19. The process of claim 18, further comprising curing the remaining polymeric layer.

20. An article formed by the process of claim 19, wherein the article is a semiconductor substrate, a flexible film for electronics, a wire isolation, a wire coating, a wire enamel, or an inked substrate.

21. A semiconductor device comprising the article of claim 20.

22. The semiconductor device of claim 21, wherein the device is an integrated circuit, a light emitting diode, a solar cell, or a transistor.

23. The photosensitive composition of claim 4, wherein the composition is substantially fluorine-free.

24. A photosensitive composition, comprising:
(a) at least one polyimide of claim 1, wherein the monomers represented by formula (Ia) comprise 1.0-90 mol % of the total amount of diamine monomers incorporated in the polyimide.

25. A photosensitive composition, comprising:
(a) at least one polyimide of claim 2, wherein the monomers represented by formula (Ia) comprise 1.0-90 mol % of the total amount of diamine monomers incorporated in the polyimide.
